(19) United States
(12) Patent Application Publication
(10) Pub. No.: US 2020/0365375 A1
(43) Pub. Date: Nov. 19, 2020

(54) STRAY PLASMA PREVENTION APPARATUS FOR SUBSTRATE PROCESS CHAMBER

(71) Applicant: APPLIED MATERIALS, INC., Santa Clara, CA (US)

(72) Inventors: Reyn WAKABAYASHI, San Jose, CA (US); Hamid NOORBAKHSH, Oakland, CA (US)

(21) Appl. No.: 15/931,304

(22) Filed: May 13, 2020

Related U.S. Application Data
(60) Provisional application No. 62/848,537, filed on May 15, 2019.

(51) Int. Cl. H01J 37/32

(52) U.S. Cl. CPC H01J 37/32495; H01J 37/32467

(57) ABSTRACT

Apparatus for stray plasma prevention for substrate processing chambers are provided herein. In some embodiments, an apparatus for preventing stray plasma in a substrate processing chamber includes: a tubular body formed of a dielectric material and defining a central opening passing therethrough from a first end to a second end of the tubular body; and a flange extending radially from the first end of the tubular body. The apparatus can be formed from a process compatible plastic material, such as polyoxymethylene (POM), polyetheretherketone (PEEK), or polytetrafluoroethylene (PTFE).

### CROSS-REFERENCE TO RELATED APPLICATIONS

This application claims benefit of U.S. provisional patent application Ser. No. 62/848,537, filed May 15, 2019 which is herein incorporated by reference in its entirety.

### FIELD

Embodiments of the present disclosure generally relate to substrate processing equipment, and more particularly to plasma enhanced substrate processing equipment.

### BACKGROUND

In the semiconductor industry, devices are fabricated by a number of manufacturing processes, such as etching and deposition, producing structures on an ever-decreasing size. Often a liner is provided in a processing chamber to minimize process byproducts from depositing on the chamber walls and from undesirably re-depositing on the substrate. In addition, many etching and deposition processes often utilize a plasma to assist the processing of the substrate. As device geometries shrink, some processes utilize higher power plasma processes. The inventors have observed that these higher power plasma processes can undesirably lead to plasma light up in locations of the chamber that were previously safe from plasma ignition or intrusion.

Accordingly, the inventors have provided a stray plasma prevention apparatus for a substrate processing chamber.

### SUMMARY

Apparatus for stray plasma prevention for substrate processing chambers are provided herein. In some embodiments, an apparatus for preventing stray plasma in a substrate processing chamber includes: a tubular body formed of a dielectric material and defining a central opening passing therethrough from a first end to a second end of the tubular body; and a flange extending radially from the first end of the tubular body. The apparatus can be formed from a process compatible plastic material, such as polyoxymethylene (POM), polyetheretherketone (PEEK), or polytetrafluoroethylene (PTFE).

In some embodiments, an apparatus for processing a substrate includes: a chamber wall having a recess formed therein on an interior volume facing side of the chamber wall; and an apparatus for preventing stray plasma partially disposed in the recess. The apparatus for preventing stray plasma can include: a tubular body formed of a dielectric material and defining a central opening passing therethrough from a first end to a second end of the tubular body and a flange extending radially from the first end of the tubular body, wherein the tubular body extends into the recess and the flange extends along the chamber wall about the recess. In some embodiments, a liner is disposed adjacent to the chamber wall, wherein the apparatus for preventing stray plasma is disposed between the chamber wall and the liner.

In some embodiments, a method of reducing or preventing stray plasma in a plasma processing chamber can include: placing a stray plasma prevention apparatus comprising a dielectric material between a chamber wall and a liner of the plasma processing chamber to define a gap between facing surfaces of the stray plasma prevention apparatus and the liner that is smaller than a distance between the chamber wall and the liner. The stray plasma prevention apparatus can be as described in any of the embodiments disclosed herein. A plasma process can be performed in the plasma processing chamber with the stray plasma prevention apparatus in place.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a sectional view of a semiconductor processing chamber having a plasma prevention apparatus in accordance with at least some embodiments of the present disclosure.

FIGS. 2A-2C are detailed partial views of a plasma prevention apparatus in accordance with at least some embodiments of the present invention.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the disclosure generally relate to a plasma prevention apparatus suitable to prevent or limit undesirable stray plasma formation in a processing chamber. The inventors have observed that the plasma prevention apparatus is particularly useful for processing in high plasma power regimes. In addition, the inventors have discovered that the disclosed apparatus is useful for preventing undesired plasma light up in a location between chamber walls and a liner adjacent the chamber wall. In addition, the inventors have discovered that the disclosed apparatus is useful for preventing undesired plasma light up between chamber walls and a liner adjacent the chamber wall in a location where a window is formed through the chamber wall, or through the chamber wall and the liner, such as is used for optical emission spectroscopy (OES), or the like.

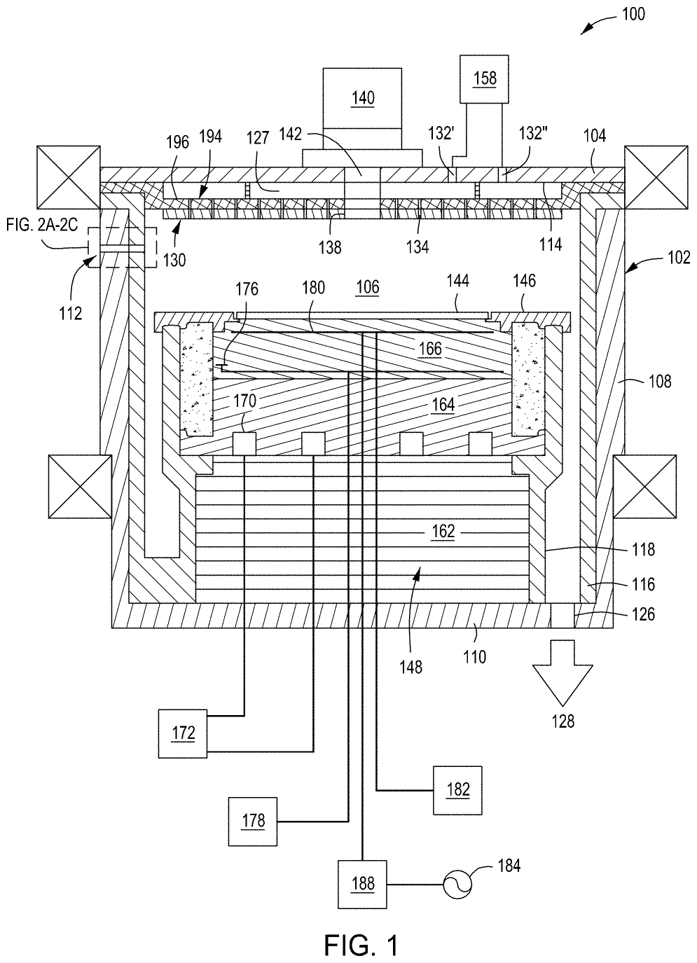

FIG. 1 is a sectional view of one embodiment of a semiconductor processing chamber 100 having a plasma prevention apparatus in accordance with at least some embodiments of the present disclosure. The processing chamber 100 includes a chamber body 102 and a lid 104 which enclose an interior volume 106. The processing chamber 100 described in FIG. 1 is illustrative and not meant to be limiting of the disclosure, as the plasma prevention apparatus described herein can be used in many different processing chambers having other configurations where undesired plasma formation in certain locations of the processing chamber is a concern.

The chamber body 102 is typically fabricated from aluminum, stainless steel or other suitable material. The chamber body 102 generally includes a chamber wall (e.g., sidewalls 108) and a bottom 110 that at least partially define an interior volume 106 of the processing chamber 100. A substrate access port (not shown) is generally defined in the sidewall 108 and is selectively sealed by a slit valve to facilitate entry and egress of a substrate 144 from the processing chamber 100.

One or more liners may be disposed in the interior volume 106 of the chamber body 102. For example, an outer liner 116 may be positioned against or on the sidewalls 108 of the chamber body 102. The outer liner 116 may be fabricated from aluminum oxide and/or coated with a plasma or halogen-containing gas resistant material such as yttria, yttria alloy, or an oxide thereof such as Y₂O₃.

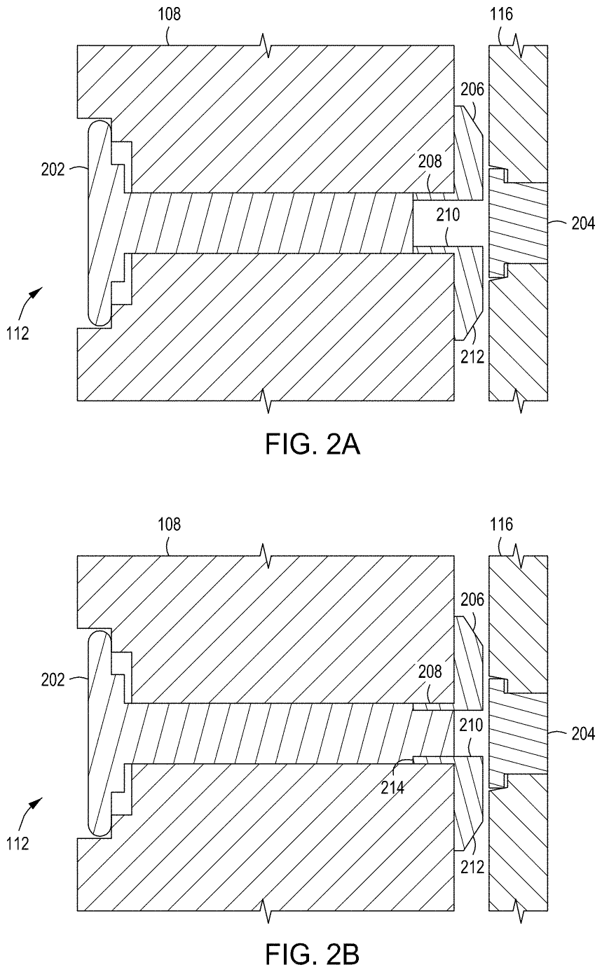

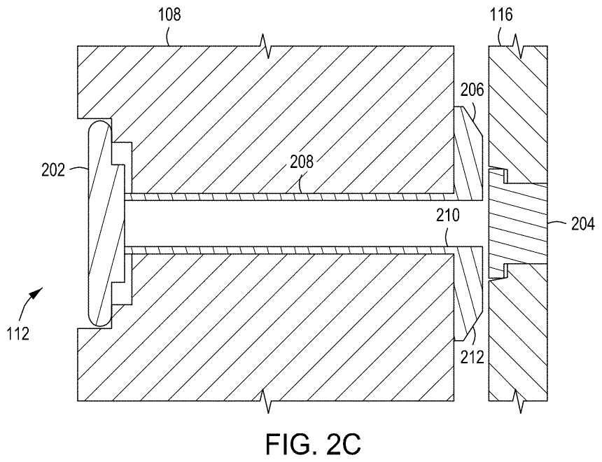

A window 112 may be formed in the processing chamber 100, for example, to facilitate process monitoring and control via optical emission spectroscopy (OES), or other techniques requiring viewing into the interior volume 106 of the processing chamber 100. The window 112 can be formed through the sidewall 108 and the liner (e.g., outer liner 116). The stray plasma prevention apparatus may be disposed between the sidewall 108 and the outer liner 116 proximate the window 112 to prevent plasma light up. The stray plasma prevention apparatus is described below in greater detail with respect to FIGS. 2A through 2C.

An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In one embodiment, the pump system 128 maintains the pressure inside the interior volume 106.

The lid 104 is sealingly supported on the sidewall 108 of the chamber body 102. The lid 104 may be opened to allow excess to the interior volume 106 of the processing chamber 100. The lid 104 may optionally include a window 142 that facilitates optical process monitoring. In one embodiment, the window 142 is comprised of quartz or other suitable material which permits the transmission of a signal utilized by an optical monitoring system 140.

A gas panel 158 is coupled to the processing chamber 100 to provide process and/or cleaning gases to the interior volume 106. Examples of processing gases may include halogen-containing gas, such as C₂F₆, SF₆, SiCl₄, HBr, NF₃, CF₄, Cl₂, CHF₃, CF₄, and SiF₄, among others, and other gases such as O₂, or N₂O. Examples of carrier gases include N₂, He, Ar, other gases inert to the process and non-reactive gases. Inlet ports 132′, and optionally 132″, are provided in the lid 104 to allow gases to be delivered from the gas panel 158 to the interior volume 106 of the processing chamber 100 through the gas distribution assembly 130.

A substrate support assembly 148 is disposed in the interior volume 106 of the processing chamber 100 below the gas distribution assembly 130. The substrate support assembly 148 holds the substrate 144 during processing. An edge deposition ring 146 is sized to receive the substrate 144 thereon while protecting the substrate support assembly 148 from plasma and deposited material. An inner liner 118 may be coated on the periphery of the substrate support assembly 148. The inner liner 118 may be a halogen-containing gas resistant material which is substantially similar to material used for the outer liner 116. In one embodiment, the inner liner 118 may be fabricated from the same material as that of the outer liner 116.

In one embodiment, the substrate support assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among other, to the base 164 and the electrostatic chuck 166.

At least one of the base 164 or the electrostatic chuck 166 may include at least one optional embedded heater 176 and a plurality of conduits 170 to control the lateral temperature profile of the substrate support assembly 148. The conduits 170 are fluidly coupled to a fluid source 172 that circulates a temperature regulating fluid therethrough. The heater 176 is regulated by a power source 178. The conduits 170 and heater 176 are utilized to control the temperature of the base 164, thus heating and/or cooling the electrostatic chuck 166.

The electrostatic chuck 166 comprises at least one clamping electrode 180 controlled using a chucking power source 182. The electrode 180 may further be coupled to one or more RF power sources 184 through a matching circuit 188 for maintaining a plasma formed form process and/or other gases within the processing chamber 100. The RF power sources 184 are generally capable of producing an RF signal having a frequency from about 50 kHz to about 3 GHz and a power of up to about 10,000 watts.

The gas distribution assembly 130 is coupled to an interior surface 114 of the lid 104. The gas distribution assembly 130 has a gas distribution plate 194. The gas distribution assembly 130 has a plenum 127 defined between the lid 104 and the gas distribution plate 194. The gas distribution plate 194 may be coupled to or have a conductive base plate 196. The conductive base plate 196 may serve as an RF electrode. The gas distribution plate 194 may be a flat disc having a plurality of apertures 134 formed in the lower surface of the gas distribution plate 194 facing toward the substrate 144. The gas distribution plate 194 may also have a portion 138 corresponding to the window 142. The portion 138 may be fabricated of similar materials as the window 142 to facilitate optical process monitoring. The apertures 134 allow the gases to flow from the inlet port 132 (shown as 132′, 132″) through the plenum 127 and out the apertures 134 into the interior volume 106 of the processing chamber 100 in a predefined distribution across the surface of the substrate 144 being processed in the processing chamber 100. The gases entering the interior volume 106 may be energized by the RF electrode for maintaining a plasma in the interior volume 106 of the processing chamber 100. Although described as having one or more RF sources coupled to the electrostatic chuck 166, one or more RF sources may alternatively or additionally be coupled to the conductive base plate 196 or some other electrode disposed in or proximate the lid 104.

FIGS. 2A-2C are detailed partial views of a plasma prevention apparatus (for example as used in the processing chamber depicted in FIG. 1) in accordance with at least some embodiments of the present disclosure. As shown in FIGS. 2A-2C, a recess is formed in the chamber wall (e.g., sidewall 108) on an interior volume facing side of the chamber wall. A stray plasma prevention apparatus 206 is partially disposed in the recess. In some embodiments. the stray plasma prevention apparatus 206 may be disposed between the sidewall 108 and the outer liner 116 proximate the window 112 to prevent plasma light up. For example, the recess may be part of the window 112 formed in the processing chamber 100, for example, through the sidewall 108 and the outer liner 116. The dimensions of the stray plasma prevention apparatus 206 may be varied depending upon the configuration of the process chamber (e.g., the thickness of the sidewall 108, the distance or gap between the sidewall 108 and the outer liner 116, or the like). However, in some embodiments, the dimensions may be selected to increase the plasma creepage length in the gap between the sidewall 108 and the outer liner 116 to be long enough to prevent plasma leakage to the chamber body (e.g., sidewall 108) or the outer liner 116 at the window 112.

The window 112 is generally formed from an opening disposed through the chamber wall (sidewall 108) and a plug 202 that seals the opening. The plug 202 extends into and partially fills the depth of the opening such that the stray plasma prevention apparatus 206 may be partially disposed in and retained in the opening. A corresponding plug 204 can be disposed through an opening in the outer liner 116 as well to provide a line of sight into the interior volume 106 from outside of the chamber body 102. The plug 202 or the plug 204 can be made of an optically transparent, process-compatible material, such as quartz.

For example, the stray plasma prevention apparatus 206 includes a tubular body 208 formed of a dielectric material and defining a central opening 210 passing therethrough from a first end to a second end of the tubular body 208. The central opening maintains the line of sight through the window 112 such that the integrity of any signal passing through the window 112 is maintained. The central opening 210 has a suitable diameter to facilitate maintaining the integrity of any signal passing through the window 112, such as about 0.2 to about 0.4 inches, or about 0.25 to about 0.35 inches, or about 0.3 inches. In some embodiments, such as depicted in FIG. 2A, the tubular body 208 can have a length of about 1.5 to about 2 inches, although other dimensions can be used in other embodiments, including longer lengths (see, e.g., FIG. 2C).

A flange 212 extends radially from the first end of the tubular body 208. In some embodiments, the flange 212 has a curved or a beveled outer radius on a side of the flange 212 opposite the second end of the tubular body 208. When inserted in the recess, the tubular body 208 extends into the recess and the flange 212 extends along the interior volume facing surface of the chamber wall about the recess. The flange 212 generally has a thickness to define a narrow gap between facing surfaces of the flange 212 and the outer liner 116. In some embodiments, the thickness of the flange 212 can be about 0.1 to about 0.15 inches, or in some embodiments, about 0.125 inches. In some embodiments, a distance measured across the gap can be between about 0.5 to about 1.5 mm, or in some embodiments, about 1 mm. For example, in some embodiments, the flange 212 can have a thickness of about ⅛ inch to define a gap of about 1 mm between facing surfaces of the flange 212 and the outer liner 116. Other dimensions may be used depending upon the spacing between the sidewall 108 and the outer liner 116 as well as the process conditions within the processing chamber when performing a plasma process. The narrow gap advantageously limits or prevents plasma leakage at the window 112 location (e.g., to the sidewall 108 or to the outer liner 116 at the window 112).

In some embodiments, the flange may have an outer diameter of about 1 to about 1.5 inches or more to advantageously increase a length of the gap to prevent plasma creepage along the gap. In some embodiments, the diameter of the flange 212 is at least about 10 times greater than the thickness of the gap (e.g., for a 1 mm gap, the flange 212 can have a diameter of at least about 0.4 inches). In some embodiments, the diameter of the flange 212 is at least about 20 times greater than the thickness of the gap (e.g., for a 1 mm gap, the flange 212 can have a diameter of at least about 0.8 inches). In some embodiments, the diameter of the flange 212 is at least about 30 times greater than the thickness of the gap (e.g., for a 1 mm gap, the flange 212 can have a diameter of at least about 1.2 inches).

In some embodiments. and as depicted in FIG. 2A, when inserted in the recess, the tubular body 208 can extend into the recess, or opening formed in the chamber wall (sidewall 108) such that the second end of the tubular body 208 terminates proximate an end surface of the plug 202. In some embodiments, and as also depicted in FIG. 2A, the plug 202 can extend predominantly through the opening and terminate shy of but proximate to the inner volume facing surface of the chamber wall (e.g., sidewall 108).

In some embodiments. and as depicted in FIG. 2B, when inserted in the recess, the tubular body 208 extends into the opening such that the second end of the tubular body 208 overlaps an end surface of the plug 202. In some embodiments, and as also depicted in FIG. 2B, a first end of the plug 202 includes a shoulder 214 defining a smaller radius in a first portion of the plug 202 proximate the first end such that the tubular body 208 overlaps the plug 202 along the first portion.

In some embodiments. and as depicted in FIG. 2C, the plug 202 can be disposed only proximate a first end of the opening proximate an outer surface of the chamber wall (e.g., sidewall 108). In such embodiments, the tubular body 208 can have a length selected to line the entire or substantially the entire opening such that the second end of the tubular body 208 terminates proximate an end surface of the plug 202 and substantially lines or covers the opening (or recess) formed in the sidewall 108.

The stray plasma prevention apparatus 206 is formed from a dielectric process compatible plastic material (e.g., able to withstand process temperatures, pressures, chemistries—such as etching chemistries, or the like). For example, the stray plasma prevention apparatus 206 can be formed from at least one of polyoxymethylene (POM) (e.g., DELRIN®), polyetheretherketone (PEEK), or polytetrafluoroethylene (PTFE). In some embodiments, the stray plasma prevention apparatus 206 is formed from PTFE (e.g., TEFLON®).

In operation, a method of reducing or preventing stray plasma in a plasma processing chamber can include placing a stray plasma prevention apparatus comprising a dielectric material between a chamber wall and a liner of the plasma processing chamber to define a gap between facing surfaces of the stray plasma prevention apparatus and the liner that is smaller than a distance between the chamber wall and the liner. The stray plasma prevention apparatus can be as described in any of the embodiments disclosed above. The plasma processing chamber can be as described above, or can at least include a chamber wall and a liner as described above. A plasma process can be performed in the plasma processing chamber with the stray plasma prevention apparatus in place. The stray plasma prevention apparatus can advantageously reduce or eliminate plasma light up, for example, near edges or corners of a window opening through the sidewall and liner of the plasma processing chamber.

While the foregoing is directed to embodiments of the present disclosure, other and further embodiments of the disclosure may be devised without departing from the basic scope thereof.

1. Apparatus for preventing stray plasma in a substrate processing chamber, comprising:
a tubular body formed of a dielectric material and defining a central opening passing therethrough from a first end to a second end of the tubular body; and
a flange extending radially from the first end of the tubular body.

2. The apparatus of claim 1, wherein the apparatus is formed from a process compatible plastic material.

3. The apparatus of claim 1, wherein the apparatus is formed from at least one of polyoxymethylene (POM), polyetheretherketone (PEEK), or polytetrafluoroethylene (PTFE).

4. The apparatus of claim 1, wherein the flange has a beveled outer radius on a side of the flange opposite the second end of the tubular body.

5. The apparatus of claim 1, wherein the apparatus consists of the tubular body and the flange.

6. The apparatus of claim 1, wherein the central opening has a diameter of about 0.2 to about 0.4 inches.

7. The apparatus of claim 1, wherein the flange has at least one of an outer diameter of at least about 1 inch or a thickness of about 0.1 to about 0.15 inches.

8. The apparatus of claim 1, wherein the apparatus consists of the tubular body and the flange, wherein the central opening has a diameter of about 0.2 to about 0.4 inches, and wherein the flange has an outer diameter of at least about 1 inch and a thickness of about 0.1 to about 0.15 inches.

9. Apparatus for processing a substrate, comprising:
a chamber wall having a recess formed therein on an interior volume facing side of the chamber wall; and
an apparatus for preventing stray plasma partially disposed in the recess, the apparatus for preventing stray plasma comprising:
a tubular body formed of a dielectric material and defining a central opening passing therethrough from a first end to a second end of the tubular body and
a flange extending radially from the first end of the tubular body, wherein the tubular body extends into the recess and the flange extends along the chamber wall about the recess.

10. The apparatus of claim 9, further comprising:
a liner disposed adjacent to the chamber wall, wherein the apparatus for preventing stray plasma is disposed between the chamber wall and the liner.

11. The apparatus of claim 10, further comprising a gap defined between facing surfaces of the flange of the apparatus for preventing stray plasma and the liner, wherein a distance measured across the gap is about 0.5 to about 1.5 mm.

12. The apparatus of claim 9, further comprising a window formed through the chamber wall, wherein the recess is part of the window.

13. The apparatus of claim 12, wherein the window is formed from an opening disposed through the chamber wall and a plug partially filling the opening, wherein the tubular body extends into the opening such that the second end of the tubular body terminates proximate an end surface of the plug.

14. The apparatus of claim 13, wherein the plug extends predominantly through the opening and terminates shy of but proximate to the interior volume facing surface of the chamber wall.

15. The apparatus of claim 13, wherein the plug is disposed only proximate a first end of the opening proximate an outer surface of the chamber wall.

16. The apparatus of claim 12, wherein the window is formed from an opening disposed through the chamber wall and a plug partially filling the opening, wherein the tubular body extends into the opening such that the second end of the tubular body overlaps an end surface of the plug.

17. The apparatus of claim 16, wherein a first end of the plug includes a shoulder defining a smaller radius in a first portion of the plug proximate the first end such that the tubular body overlaps the plug along the first portion.

18. A method of reducing or preventing stray plasma in a plasma processing chamber, comprising:
placing a stray plasma prevention apparatus comprising a dielectric material between a chamber wall and a liner of the plasma processing chamber to define a gap between facing surfaces of the stray plasma prevention apparatus and the liner that is smaller than a distance between the chamber wall and the liner.

19. The method of claim 18, wherein the chamber wall includes a recess formed therein on an interior volume facing side of the chamber wall, and further comprising placing the stray plasma prevention apparatus partially within the recess.

20. The method of claim 19, wherein a distance measured across the gap between facing surfaces of the stray plasma prevention apparatus and the liner is about 0.5 to about 1.5 mm.
